(19) United States
(12) Patent Application Publication
(10) Pub. No.: US 2014/0183721 A1
(43) Pub. Date: Jul. 3, 2014

(54) SEMICONDUCTOR PACKAGE AND FABRICATION METHOD THEREOF

(71) Applicant: SILICONWARE PRECISION INDUSTRIES CO., LTD., Taichung (TW)

(72) Inventors: Yan-Heng Chen, Taichung (TW); Chiang-Cheng Chang, Taichung (TW); Jung-Pang Huang, Taichung (TW); Hsi-Chang Hsu, Taichung (TW); Yan-Yi Liao, Taichung (TW)

(73) Assignee: SILICONWARE PRECISION INDUSTRIES CO., LTD., Taichung (TW)

(21) Appl. No.: 13/846,579

(22) Filed: Mar. 18, 2013

(30) Foreign Application Priority Data
Jan. 3, 2013 (TW) 102100086

(51) Int. Cl. H01L 21/56; H01L 23/31

(52) U.S. Cl. CPC H01L 21/56; H01L 23/31
USPC 257/734; 438/126

(57) ABSTRACT

A fabrication method of a semiconductor package is provided, which includes the steps of: providing a carrier having an adhesive layer and at least a semiconductor element having a protection layer; disposing the semiconductor element on the adhesive layer of the carrier through the protection layer; forming an encapsulant on the adhesive layer of the carrier for encapsulating the semiconductor element; removing the carrier and the adhesive layer to expose the protection layer from the encapsulant; and removing the protection layer to expose the semiconductor element from the encapsulant. Since the semiconductor element is protected by the protection layer against damage during the process of removing the adhesive layer, the product yield is improved.

### BACKGROUND OF THE INVENTION

1. Field of the Invention

The present invention relates to semiconductor packages and fabrication methods thereof, and more particularly, to a semiconductor package and a fabrication method thereof for improving product yield.

2. Description of Related Art

Along with the development of semiconductor technologies, various types of packages have been developed for semiconductor products. Particularly, chip scale packages have been developed to meet the miniaturization trend. A chip scale package is characterized in that the package has a size substantially equal to or slightly larger than that of a chip.

However, in the above-described chip scale package, the size of the chip or the area of an active surface of the chip limits formation of conductive traces on the chip or application of redistribution layer (RDL) technologies. Further, as the chip is more integral and smaller in size, the area of the chip may be not sufficient for mounting solder balls for electrically connecting an external device. Therefore, a semiconductor package having a fan-out structure is provided, in which a build-up layer is formed on a chip so as to provide sufficient surface area for mounting more I/O pins or solder balls.

FIGS. 1A to 1F are schematic cross-sectional views showing a fabrication method of a semiconductor package having a fan-out structure according to the prior art.

Referring to FIGS. 1A, 1A′ and 1A″, a carrier 10 is provided, and a bonding layer 100 and an adhesive layer 101 are sequentially formed on the carrier 10. A semiconductor substrate 11′ is provided, which has a plurality of semiconductor elements 11 each having an active surface 11a and a non-active surfaces 11b opposite to the active surface 11a. The active surface 11a has a plurality of electrode pads 110 and a passivation layer 111 thereon and the electrode pads 110 are exposed from the passivation layer 111.

Referring to FIG. 1B, a singulation process is performed to the semiconductor substrate 11′ along cutting paths L (as shown in FIGS. 1A′ and 1A″) so as to obtain a plurality of singulated semiconductor elements 11. Thereafter, the semiconductor elements 11 are disposed on the adhesive layer 101 through the active surfaces 11a thereof, and then the adhesive layer 101 is cured.

Referring to FIG. 1C, by using a substrate 13, an encapsulant 12 is laminated on the adhesive layer 101 for encapsulating the semiconductor elements 11.

Referring to FIG. 1D, the carrier 10 and the bonding layer 100 are removed to expose the adhesive layer 101.

Referring to FIG. 1E, since the adhesive layer 101 remains on the semiconductor elements 11 and the encapsulant 12 after the carrier 10 and the bonding layer 100 are removed and the adhesive layer 101 cannot be removed by a solvent, a plasma cleaning process is performed to remove the adhesive layer 101. As such, the electrode pads 110 of the semiconductor elements 11 are exposed from a surface of the encapsulant 12, and the active surfaces 11a of the semiconductor elements 11 with the electrode pads 110 and the passivation layer 111 are flush with the surface of the encapsulant 12.

Referring to FIG. 1F, a redistribution layer 15 is formed on the active surfaces 11a of the semiconductor elements 11 and the surface of the encapsulant 12. An insulating layer 16 is further formed on the redistribution layer 15, the active surfaces 11a of the semiconductor elements 11 and the surface of the encapsulant 12, and portions of the redistribution layer 15 are exposed from the insulating layer 16 for mounting conductive elements 17. Thereafter, a singulation process is performed along a cutting path S to obtain a plurality of semiconductor packages 1.

In the semiconductor package 1, the redistribution layer 15 serves as a fan-out structure to facilitate redistribution of bonding pads of the semiconductor elements 11. Therefore, the conductive elements 17 are mounted on the exposed portions of the redistribution layer 15 instead of directly on the electrode pads 110.

However, after the carrier 10 and the bonding layer 100 are removed, the adhesive layer 101 remaining on the semiconductor elements 11 is not evenly distributed, as show in FIG. 1D. Therefore, referring to FIG. 1E, when the plasma cleaning process is performed to the adhesive layer 101, portions of the adhesive layer 101 may be over-cleaned so as to damage the active surfaces of the semiconductor elements 11 with the electrode pads 110 and the passivation layer 111. As such, the semiconductor elements 11 have an uneven surface k1 as shown in FIG. 1E and consequently the product yield is reduced.

Therefore, there is a need to provide a semiconductor package and a fabrication method thereof so as to overcome the above-described drawbacks.

### SUMMARY OF THE INVENTION

In view of the above-described drawbacks, the present invention provides a semiconductor package, which comprises: an encapsulant having a first surface and a second surface opposite to the first surface; and a semiconductor element embedded in the encapsulant, wherein the semiconductor element has an active surface with a plurality of electrode pads and a non-active surface opposite to the active surface, and the active surface of the semiconductor element is exposed from the first surface of the encapsulant and different in level from the first surface of the encapsulant.

The present invention further provides a fabrication method of a semiconductor package, which comprises the steps of: providing a carrier having an adhesive layer and at least a semiconductor element having a protection layer; disposing the semiconductor element on the adhesive layer of the carrier through the protection layer; forming an encapsulant on the adhesive layer of the carrier for encapsulating the semiconductor element; removing the carrier and the adhesive layer to expose the protection layer from a first surface of the encapsulant; and removing the protection layer to expose a surface of the semiconductor element from the first surface of the encapsulant.

In the above-described method, the carrier can be made of glass. The adhesive layer can be a UV-curing adhesive layer such that the method further comprises curing the adhesive layer through UV irradiation before forming the encapsulant. The carrier can further have a bonding layer allowing the adhesive layer to be formed thereon and the step of removing the carrier comprises removing the bonding layer along with the carrier. In the above-described method, the protection layer can be made of photoresist, polyimide or soluble polymer.

In the above-described method, the adhesive layer can be removed through a plasma cleaning process. The plasma cleaning process can use a plasma comprising CF₄.

In the above-described method, the protection layer can be removed by a solvent.

In the above-described method, the semiconductor element can have an active surface with a plurality of electrode pads and a non-active surface opposite to the active surface, and the protection layer is formed on the active surface of the semiconductor element for covering the electrode pads. After the protection layer is removed, the electrode pads are exposed from the first surface of the encapsulant.

In the above-described method, after the protection layer is removed, the exposed surface of the semiconductor element can be different in level from the first surface of the encapsulant.

In the above-described package and method, at least a substrate can be disposed on the encapsulant. The encapsulant can be laminated on the adhesive layer of the carrier by the substrate and the carrier. The substrate can be made of glass.

In the above-described package and method, a level difference of about 10 um can be formed between the exposed surface of the semiconductor element and the first surface of the encapsulant.

In the above-described package and method, after the protection layer is removed, a circuit layer can be formed on the first surface of the encapsulant and the exposed surface of the semiconductor element, and the circuit layer is electrically connected to the semiconductor element.

Therefore, during the process of removing the adhesive layer, the semiconductor element is protected by the protection layer against any damage caused by over-cleaning as in the prior art, thereby improving the product yield.

### BRIEF DESCRIPTION OF DRAWINGS

FIGS. 1A to 1F are schematic cross-sectional views showing a fabrication method of a semiconductor package according to the prior art, wherein FIG. 1A″ is an upper view of FIG. 1A′; and

FIGS. 2A to 2H are schematic cross-sectional views showing a fabrication method of a semiconductor package according to the present invention.

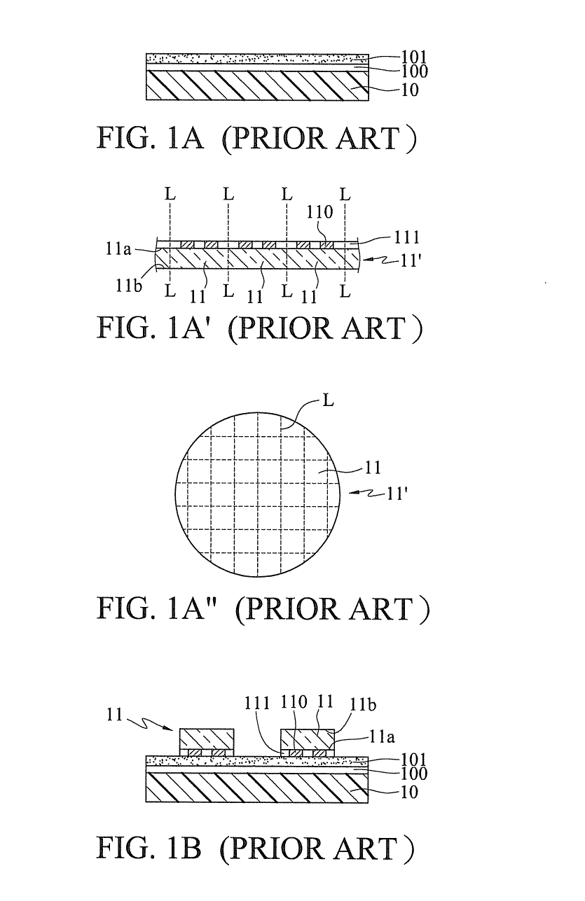

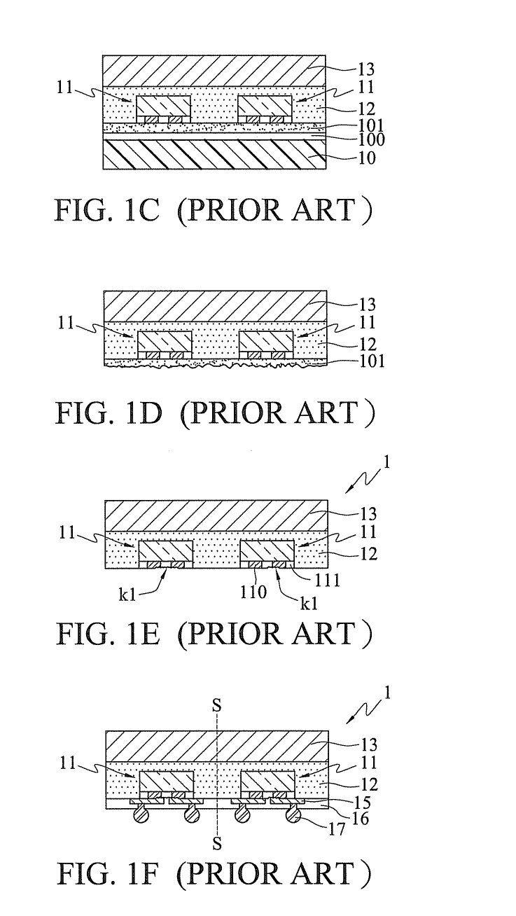

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “upper”, “lower”, “a” etc. are merely for illustrative purpose and should not be construed to limit the scope of the present invention.

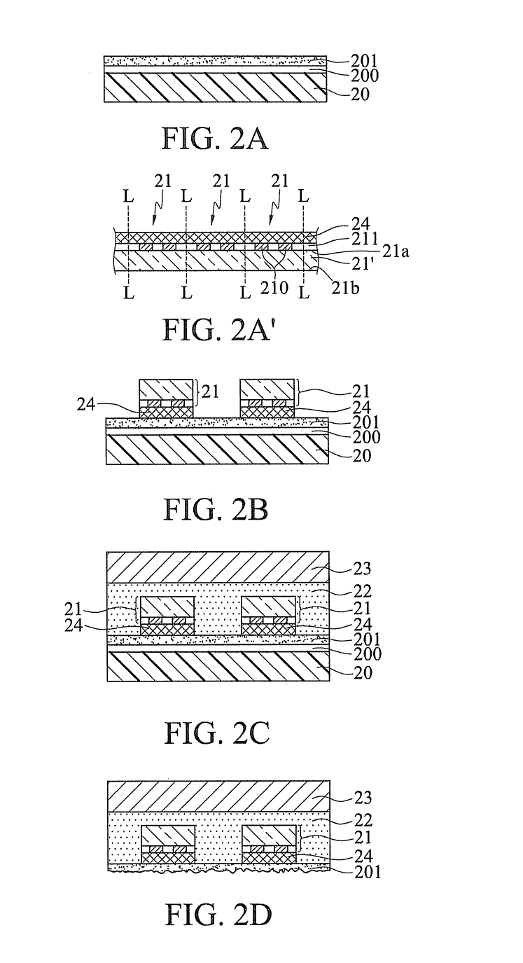

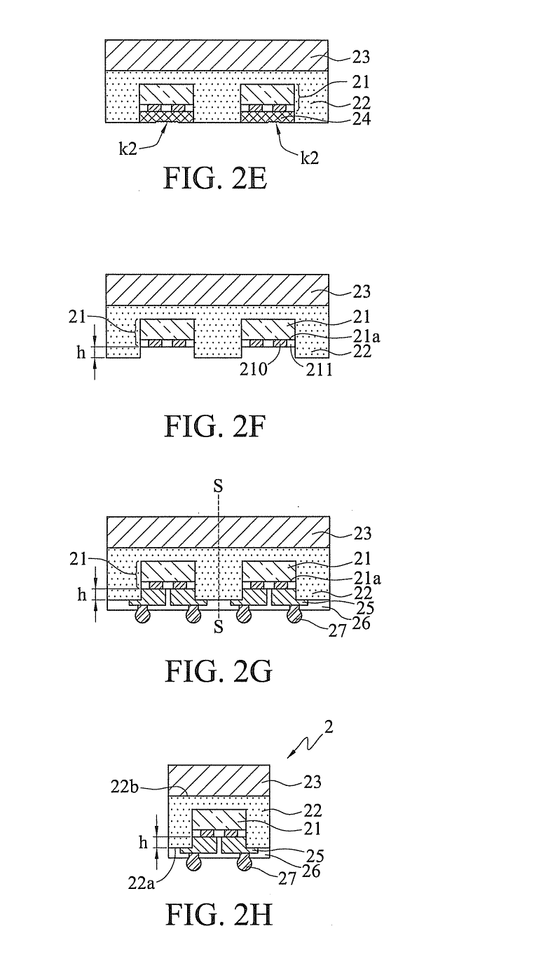

FIGS. 2A to 2G are schematic cross-sectional views showing a fabrication method of a semiconductor package 2 according to the present invention.

Referring to FIGS. 2A and 2A′, a semiconductor substrate 21′ and a carrier 20 with an adhesive layer 201 are provided.

In the present embodiment, the carrier 20 is made of glass, and the adhesive layer 201 is a UV-curing adhesive layer. Therefore, a bonding layer 200 is formed on the carrier 20 by chemical vapor deposition (CVD) and then the adhesive layer 201 is coated on the bonding layer 200 so as to be bonded to the carrier 20 through the bonding layer 200.

The semiconductor substrate 21′ is a wafer or a silicon-containing substrate having a plurality of semiconductor elements 21. Each of the semiconductor elements 21 has an active surface 21a and a non-active surface 21b opposite to the active surface 21a. The active surface 21a has a plurality of electrode pads 210 and a passivation layer 211 thereon and the electrode pads 210 are exposed from the passivation layer 211. The electrode pads 210 can be made of copper or aluminum. The passivation layer 211 can be made of SiO₂ or SiN₄, and the thickness of the passivation layer 211 is very small and negligible.

Further, a protection layer 24 is formed on the active surfaces 21a of the semiconductor elements 21 for covering the electrode pads 210 and the passivation layer 211. The protection layer 24 can be made of photoresist, polyimide or soluble polymer.

Referring to FIG. 2B, a singulation process is performed to the semiconductor substrate 21′ along cutting paths L of FIG. 2A′ so as to obtain a plurality of singulated semiconductor elements 21. Then, the semiconductor elements 21 are disposed on the adhesive layer 201 through the protection layer 24 and the adhesive layer 201 is further cured through UV irradiation.

Referring to FIG. 2C, an encapsulant 22 is formed on the adhesive layer 201 of the carrier 20 for encapsulating the semiconductor elements 21, and a substrate 23 is disposed on the encapsulant 22.

In the present embodiment, the encapsulant 22 is laminated on the adhesive layer 201 of the carrier 20 by the substrate 23 and the carrier 20.

The encapsulant 22 can be made of epoxy, ABF (Ajinomoto Build-up Film), polyimide etc. The substrate 23 can be made of, but not limited to, glass.

Referring to FIG. 2D, the carrier 20 and the bonding layer 200 are removed to expose the adhesive layer 201.

Referring to FIG. 2E, the adhesive layer 201 is removed by plasma cleaning to expose the protection layer 24 from a surface of the encapsulant 22.

In the present embodiment, the plasma cleaning process uses a plasma containing CF₄ and oxygen gases.

Referring to FIG. 2F, the protection layer is removed by a solvent to expose the electrode pads 210 of the active surfaces 21a of the semiconductor elements 21 from the surface of the encapsulant 22, and the active surfaces 21a are lower than the surface of the encapsulant 22. That is, the semiconductor elements 21 are entirely recessed in the encapsulant 22.

In the present embodiment, a height difference, i.e, a level difference h of about 10 um is formed between the active surfaces 21a of the semiconductor elements 21 and the surface of the encapsulant 22.

Referring to FIG. 2G a circuit layer 25 such as a redistribution layer is formed on the active surfaces 21a of the semiconductor elements 21 and the surface of the encapsulant 22. An insulating layer 26 is further formed on the circuit layer 25, the active surfaces 21a of the semiconductor elements 21 and the surface of the encapsulant 22, and portions of the circuit layer 25 are exposed from the insulating layer 26 for mounting conductive elements 27.

In the present embodiment, the insulating layer 26 is, but not limited to, a solder mask layer. The conductive elements 27 can be solder balls, bumps or posts.

In other embodiments, several circuit layers 25 can be formed.

Referring to FIG. 2H, a singulation process is performed along a cutting path S of FIG. 2G to obtain a plurality of semiconductor packages 2.

According to the present invention, the protection layer 24 is formed on the active surfaces 21a of the semiconductor elements 21 such that the semiconductor elements 21 are disposed on the adhesive layer 201 through the protection layer 24. Therefore, during the plasma cleaning process of the adhesive layer 201, only a surface k2 (as shown in FIG. 2E) of the protection layer 24 may be damaged by over-cleaning, thereby protecting the active surfaces 21a of the semiconductor elements 21 against any damage caused by over-cleaning as in the prior art and improving the product yield.

The present invention further provides a semiconductor package 2, which has: an encapsulant 22 having a first surface 22a, i.e., a lower surface, and a second surface 22b, i.e, an upper surface, opposite to the first surface 22a; a semiconductor element 21 embedded in the encapsulant 22, wherein the semiconductor element 21 has an active surface 21a with a plurality of electrode pads 210 and a non-active surface 21b opposite to the active surface 21a, and the active surface 21a of the semiconductor element 21 is exposed from the first surface 22a of the encapsulant 22 and different in level from the first surface 22a of the encapsulant 22; a circuit layer 25 formed on the first surface 22a of the encapsulant 22 and the active surface 21a of the semiconductor element 21 and electrically connected to the electrode pads 210; and a substrate 23 disposed on the second surface 22b of the encapsulant 22.

The substrate 23 can be made of glass.

According to the present invention, a protection layer is formed on a surface of a semiconductor element so as for the semiconductor element to be disposed on an adhesive layer through the protection layer. Therefore, during a process of removing the adhesive layer, the surface of the semiconductor element can be protected by the protection layer from being damaged, thereby improving the product yield.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
an encapsulant having a first surface and a second surface opposite to the first surface; and
a semiconductor element embedded in the encapsulant, wherein the semiconductor element has an active surface with a plurality of electrode pads and a non-active surface opposite to the active surface, and the active surface of the semiconductor element is exposed from the first surface of the encapsulant and different in level from the first surface of the encapsulant.

2. The package of claim 1, further comprising a substrate disposed on the second surface of the encapsulant.

3. The package of claim 2, wherein the substrate is made of glass.

4. The package of claim 1, wherein a level difference of about 10 um is formed between the active surface of the semiconductor element and the first surface of the encapsulant.

5. The package of claim 1, further comprising a circuit layer formed on the first surface of the encapsulant and the active surface of the semiconductor element and electrically connected to the electrode pads.

6. A fabrication method of a semiconductor package, comprising the steps of:
providing a carrier having an adhesive layer and at least a semiconductor element having a protection layer;
disposing the semiconductor element on the adhesive layer of the carrier through the protection layer;
forming an encapsulant on the adhesive layer of the carrier for encapsulating the semiconductor element;
removing the carrier and the adhesive layer to expose the protection layer from a first surface of the encapsulant; and
removing the protection layer to expose a surface of the semiconductor element from the first surface of the encapsulant.

7. The method of claim 6, wherein the carrier is made of glass.

8. The method of claim 6, wherein the adhesive layer is a UV-curing adhesive layer.

9. The method of claim 8, before forming the encapsulant, further comprising curing the adhesive layer through UV irradiation.

10. The method of claim 6, wherein the carrier further has a bonding layer allowing the adhesive layer to be formed thereon.

11. The method of claim 10, wherein the step of removing the carrier comprises removing the bonding layer along with the carrier.

12. The method of claim 6, wherein the semiconductor element has an active surface with a plurality of electrode pads and a non-active surface opposite to the active surface, and the protection layer is formed on the active surface of the semiconductor element for covering the electrode pads.

13. The method of claim 12, wherein the electrode pads are exposed from the first surface of the encapsulant after the protection layer is removed.

14. The method of claim 12, wherein the active surface of the semiconductor element is lower than the first surface of the encapsulant.

15. The method of claim 6, wherein the protection layer is made of photoresist, polyimide or soluble polymer.

16. The method of claim 6, further comprising disposing at least a substrate on a second surface of the encapsulant opposite to the first surface.

17. The method of claim 16, wherein the substrate is made of glass.

18. The method of claim 16, wherein the encapsulant is laminated on the adhesive layer of the carrier by the substrate and the carrier.

19. The method of claim 6, wherein the adhesive layer is removed through a plasma cleaning process.

20. The method of claim 19, wherein the plasma cleaning process uses a plasma comprising CF₄.

21. The method of claim 6, wherein the protection layer is removed by a solvent.

22. The method of claim 6, wherein after the protection layer is removed, the exposed surface of the semiconductor element is different in level from the first surface of the encapsulant.

23. The method of claim 22, wherein a level difference of about 10 um is formed between the exposed surface of the semiconductor element and the first surface of the encapsulant.

24. The method of claim 6, further comprising forming a circuit layer on the first surface of the encapsulant and the exposed surface of the semiconductor element, wherein the circuit layer is electrically connected to the semiconductor element.
